(19) United States
(12) Patent Application Publication
(10) Pub. No.: US 2020/0340137 A1
(43) Pub. Date: Oct. 29, 2020

(54) METHOD AND DEVICE FOR CONTROLLING SAFE LIFTING OF SILICON MELT CRUCIBLE

(71) Applicant: ZING SEMICONDUCTOR CORPORATION, Shanghai (CN)

(72) Inventors: HANYI HUANG, Shanghai (CN); WEIMIN SHEN, Shanghai (CN); GANG WANG, Shanghai (CN)

(21) Appl. No.: 16/830,729

(22) Filed: Mar. 26, 2020

(30) Foreign Application Priority Data
Apr. 23, 2019 (CN) 201910329242.8

(51) Int. Cl. C30B 15/20; C30B 29/06

(52) U.S. Cl. CPC C30B 15/20; C30B 29/06

(57) ABSTRACT

The invention provides a method and a device for controlling the safe lifting of a silicon melt crucible. The method includes: obtaining an initial position height POS₀ of the crucible, an initial liquid level D₀ of the silicon melt in the crucible, and an initial distance MG₀ between the liquid level of the silicon melt and the deflector; obtaining the current position height of the crucible POS_{L} and the current liquid level D_{L} of the silicon melt in the crucible at a current silicon ingot growth length L; judging whether the current position height of the crucible is safe or not at the current silicon ingot growth length L according to the initial position height POS₀, the current position height POS_{L}, the initial liquid level D₀, and the current liquid level D_{L}. According to the method and device for controlling the safe lifting of a silicon melt crucible according to the present invention, damage to the crucible due to the up and down movement of the crucible during the pulling process is avoided, and the level of the silicon melt stability guarantees the stable growth of silicon ingots.

### CROSS-REFERENCE TO RELATED APPLICATIONS

This application claims priority to P.R.C. Patent Application No. 201910329242.8 titled “method and device for controlling safe lifting of silicon melt crucible” filed on Apr. 23, 2019, with the State Intellectual Property Office of the People's Republic of China (SIPO).

### TECHNICAL FIELD

The present disclosure relates to semiconductor manufacturing technology, and particularly, it relates to a method and device for controlling the safe lifting of a silicon melt crucible.

### BACKGROUND

The Czochralski Process (Cz) method is an important method for preparing silicon and single crystals in semiconductors and solar energy manufacturing industries. The high-purity silicon material placed in a crucible is heated and melted by a thermal field composed of a carbon material, and then the seed crystal is immersed in a single crystal rod is finally obtained in the melt through a series of processes such as introduction, shouldering, equal diameter, finishing, and cooling etc.

Referring to FIG. 1, a schematic diagram of a semiconductor crystal growth apparatus is shown. The semiconductor crystal growth device includes a furnace body 1, and a crucible 11 is provided in the furnace body 1, and a heater 12 for heating the crucible 11 is provided outside the crucible 11, and a silicon melt 13 is contained in the crucible 11.

A lifting device 14 is provided on the top of the furnace body 1. Driven by the lifting device 14, the seed crystal is pulled and pulled out of the silicon ingot 10 from the liquid surface of the silicon melt, and a heat shield device is provided around the silicon ingot 10, By way of example, as shown in FIG. 1, the heat shield device includes a deflector 16, which is provided in a conical barrel type. As a heat shield device, it is used to isolate the quartz crucible and the crucible during the crystal growth process. The thermal radiation generated by the silicon melt on the crystal surface increases the cooling rate and axial temperature gradient of the ingot, and increases the number of crystal growth. On the other hand, it affects the thermal field distribution on the surface of the silicon melt, and avoids the center and the axial temperature gradient of the edge is too large to ensure stable growth between the crystal rod and the liquid level of the silicon melt. At the same time, the baffle is also used to guide the inert gas introduced from the upper part of the crystal growth furnace to make it more comparable. A large flow rate passes through the surface of the silicon melt to achieve the effect of controlling the oxygen content and impurity content in the crystal.

In order to achieve stable growth of the silicon ingot, a driving device 15 for driving the crucible 11 to rotate and move up and down is provided at the bottom of the furnace body 1. The driving device 15 drives the crucible 11 to keep rotating during the crystal pulling process to reduce the heat of the silicon melt the asymmetry makes the silicon crystal columns grow equally. The driving device 15 drives the crucible 11 to move up and down in order to ensure that the silicon melt has a stable liquid surface position and stability of the growth of the ingot.

However, in the process that the driving device 15 drives the crucible 11 to move up and down, the crucible position often exceeds or falls below the predetermined position, which causes the liquid level of the silicon melt to be higher or lower, which affects the quality of crystal growth. After moving upward beyond the liquid level of the silicon melt to a certain extent, it comes into contact with the deflector 16 and causes damage to the device.

For this reason, it is necessary to propose a new method and device for controlling the safe lifting of the silicon melt crucible to solve the problems in the prior art.

### SUMMARY

A series of simplified forms of concepts are introduced in the summary section, which will be explained in further detail in the detailed description section. The summary of the present invention does not mean trying to define the key features and necessary technical features of the claimed technical solution, let alone trying to determine the protection scope of the claimed technical solution.

The invention provides a method for controlling the safe lifting of a silicon melt crucible. The method includes the steps of:
obtaining an initial position height POS₀ of the crucible, an initial liquid level D₀ of the silicon melt in the crucible, and an initial distance MG₀ between the liquid level of the silicon melt in the crucible and the deflector;
obtaining a current position height POS_{L} of the crucible and a current liquid level height D_{L} of the silicon melt in the crucible at a current silicon ingot growth length L;
determining whether the current position height of the crucible is safe or not at the current silicon ingot growth length L according to the initial position height POS₀, the current position height POS_{L}, the initial liquid level D₀, and the current liquid level height D_{L}.

In accordance with some embodiments, whether the current position height of the crucible is safe or not at the current silicon ingot growth length L is determined according to the following rules:
when α₀POSL−α₁POS₀<β₀D₀−β₁D_{L}+β₂MG₀+L_{S}, the current position height of the crucible is highly secure;
when α₀POS_{L}−α₁POS₀>β₀D₀−β₁D_{L}+β₂MG₀+L_{S}, the current position height of the crucible is not safe, and the L_{S} is a preset safety control height margin.

In accordance with some embodiments, the method further comprises judging whether the position of the liquid surface of the silicon melt in the crucible is stable or not at the current silicon ingot growth length L according to the initial position height POS₀, the current position height POS_{L}, the initial liquid level height D₀, and the current liquid level height D_{L}.

Exemplarily, whether the position of the liquid surface of the silicon melt in the crucible is stable or not is judged according to the following rules:
when α₀POS_{L}−α₁POS₀<β₀D₀−β₁D_{L}+β₂MG₀+L_{U} and α₀POS_{L}−α₁POS₀>β₀D₀−β₁D_{L}+β₂MG₀−L_{L}, the position of the silicon melt liquid level in the crucible is stable;

when α₀POS_{L}−α₁POS₀>β₀D₀−β₁D_{L}+β₂MG₀+L_{U} or α₀POS_{L}−α₁POS₀<β₀D₀−β₁D_{L}+β₂MG₀−L_{L}, the position of the silicon melt liquid level in the crucible is unstable;

among them, α₀, α₁, β₀, β₁ and β₂ are coefficient factors, L_{U} and L_{L} are the control margins for setting the upper and lower liquid level limits, respectively.

Exemplarily, the step of obtaining the current liquid level D_{L} of the liquid level of the silicon melt in the crucible comprises:
obtaining an initial mass G₀ of the silicon melt in the crucible and a current mass G_{L} of the silicon ingot at the current silicon ingot growth length L;
obtaining a volume Vᵣ of the silicon melt currently remaining in the crucible according to the initial mass G₀ of the silicon melt in the crucible and the current mass G_{L} of the produced silicon ingot;
calculating the current liquid level D_{L} of the of the silicon melt in the crucible according to the volume Vr of the current remaining silicon melt of the crucible and the diameter of the crucible.

In accordance with some embodiments, the obtaining the current mass G_{L} of the silicon ingot at the current silicon ingot growth length L is obtained by calculating the following formula:

G_{L}=(∫ Area_{L} dL)*ρ_{Si}.

In accordance with some embodiments, the acquiring the quality G_{L} of the currently generated silicon ingot is obtained by directly measuring the quality of the currently generated silicon ingot.

The invention also provides a method for controlling the safe lifting of a silicon melt crucible, comprising:
obtaining a current position height POS_{L} of the crucible at a current silicon ingot growth length L;
obtaining position heights POS_{Li} of the crucible when N silicon ingots have a growth length of L, where i=1, 2 . . . N;
obtaining a position median POSM_{L} and a position standard deviation DEV_{L} of the position POS_{Li} of the crucible;
determining whether the current position height of the crucible is safe or not at the current silicon ingot growth length L according to the position height POS_{L}, the position median POSM_{L}, and the position standard deviation DEV_{L}.

In accordance with some embodiments, whether the current position height of the crucible is safe or not at the current silicon ingot growth length L is determined according to the following rules:
when γ₀POS_{L}−γ₁POSM_{L}<DEV_{L}×y_{S}, the current position height of the crucible is highly safe;
when γ₀POS_{L}−γ₁POSM_{L}>DEV_{L}×y_{S}, the current position height of the crucible is highly unsafe;
wherein γ₀ and γ₁ are coefficient factors and y_{S} is a preset safety control factor.

In accordance with some embodiments, the method further comprises determining whether the position of the liquid level of the silicon melt in the crucible is stable or not at the current silicon ingot growth length L according to the position height POS_{L}, the position median POSM_{L}, and the position standard deviation DEV_{L}.

Exemplarily, whether the position of the liquid surface of the silicon melt in the crucible is stable or not at the current silicon ingot growth length L is determined according to the following rules:
when γ₀POS_{L}−γ₁POSM_{L}<DEV_{L}×y_{U} and γ₀POS_{L}−γ₁POSM_{L}>DEV_{L}×y_{L}, the position of the liquid level of the silicon melt in the crucible is stable;
when γ₀POS_{L}−γ₁POSM_{L}>DEV_{L}×y_{U} or γ₀POS_{L}−γ₁POSM_{L}<DEV_{L}×y_{L}, the position of the liquid level of the silicon melt in the crucible is unstable;
wherein γ₀ and γ₁ are coefficient factors, and y_{U} and y_{L} are the highest factor and the lowest factor respectively.

In accordance with some embodiments, a method for obtaining the position POSᵢ of the crucible when the length of the N silicon ingots is L comprises:
obtaining position heights of the crucible for each silicon crystal rod at each M length of growth;
obtaining each position POS_{Li} for each silicon ingot of the crucible at the current silicon ingot growth length L from a plurality of the position heights POS_{iM} of each silicon ingot.

In accordance with some embodiments, a method for obtaining the position median POSM_{L} and the position standard deviation DEV_{L} of the position POSᵢ of the crucible comprises:
obtaining the median position POSM_{M} and position standard deviation DEV_{L} of the crucible for each length of growth M according to the POS_{iM}, and plotting them into a table or curve, respectively;
obtaining from the table or curve the median position POSM_{L} and position standard deviation DEV_{L} of the crucible at the current silicon ingot growth length L.

In accordance with some embodiments, when it is judged that the position of the crucible is outside the safe range, the crucible is locked at the current position without moving up and down.

In accordance with some embodiments, when it is judged that the position of the liquid surface in the crucible is unstable, an alarm is issued.

The invention also provides a device for controlling the safe lifting of a silicon melt crucible, comprising:
a memory and a processor storing executable computer program instructions, and when the processor executes the executable computer program instructions, the processor executes the method according to any one of the foregoing.

In accordance with some embodiments, it further comprises a locking device, and when the processor determines that the position of the crucible is outside the safe range, the locking device locks the crucible at the current position without moving up and down.

In accordance with some embodiments, it further comprises an alarm device, and when the processor determines that the position of the liquid surface in the crucible is unstable, the alarm device issues an alarm.

According to the method and device for controlling the safe lifting of a silicon melt crucible according to the present invention, it is judged whether the current position of the crucible during the crystal pulling process is within a safe range by the crucible position and the liquid level position in the crucible, thereby avoiding the up and down movement of the crucible exceeds the limit and damages the crucible during the crystal pulling. At the same time, during the up and down movement of the crucible, the stability of the liquid level of the silicon melt located therein further ensures the stable growth of the silicon ingot.

### BRIEF DESCRIPTION OF THE DRAWINGS

Exemplary embodiments will be more readily understood from the following detailed description when read in conjunction with the appended drawings, in which:

FIG. 1 is a schematic structural diagram of a semiconductor crystal growth device;

FIG. 2 is a flowchart of a method for controlling safe lifting of a silicon melt crucible according to an embodiment of the present invention;

FIG. 3 is a flowchart of a method for controlling safe lifting of a silicon melt crucible according to another embodiment of the present invention

### DETAILED DESCRIPTION

In the following description, numerous specific details are given to provide a more thorough understanding of the present invention. However, it will be apparent to one skilled in the art that the present invention may be practiced without one or more of these details. In other examples, in order to avoid confusion with the present invention, some technical features known in the art are not described.

For a thorough understanding of the present invention, a detailed description will be provided in the following description to illustrate the method according to the present invention. Obviously, the implementation of the present invention is not limited to the specific details familiar to those skilled in the semiconductor field. The preferred embodiments of the present invention are described in detail below. However, in addition to these detailed descriptions, the present invention may have other embodiments.

It should be noted that terminology used herein is for the purpose of describing particular embodiments only and is not intended to limit the exemplary embodiments according to the present invention. As used herein, the singular forms are intended to include the plural forms as well, unless the context clearly indicates otherwise. In addition, it should also be understood that when the terms “including” and/or “including” are used in this specification, they indicate the presence of stated features, integers, steps, operations, elements and/or components, but do not exclude the presence or Add one or more other features, wholes, steps, operations, elements, components, and/or combinations thereof.

Now, exemplary embodiments according to the present invention will be described in more detail with reference to the accompanying drawings. These exemplary embodiments may, however, be embodied in many different forms and should not be construed as limited to the embodiments set forth herein. It should be understood that these embodiments are provided so that this disclosure will be thorough and complete, and will fully convey the concept of the exemplary embodiments to those skilled in the art. In the drawings, the thicknesses of layers and regions are exaggerated for the sake of clarity, and the same elements are denoted by the same reference numerals, and their descriptions will be omitted.

### Embodiment One

In order to solve the technical problems in the prior art, the present invention provides a method for controlling the safe lifting of a silicon melt crucible. The method includes:
obtaining the initial position height POS₀ of the crucible, the initial liquid level D₀ of the silicon melt in the crucible, and the initial distance MG₀ between the liquid level of the silicon melt in the crucible and the deflector;
obtaining the current position height POS_{L} of the crucible and the current liquid level height D_{L} of the silicon melt in the crucible when the currently grown silicon ingot length is L;
determining whether the current position height of the crucible is safe or not at the current silicon ingot growth length L according to the initial position height POS₀, the current position height POS_{L}, the initial liquid level D₀, and the current liquid level D_{L}.

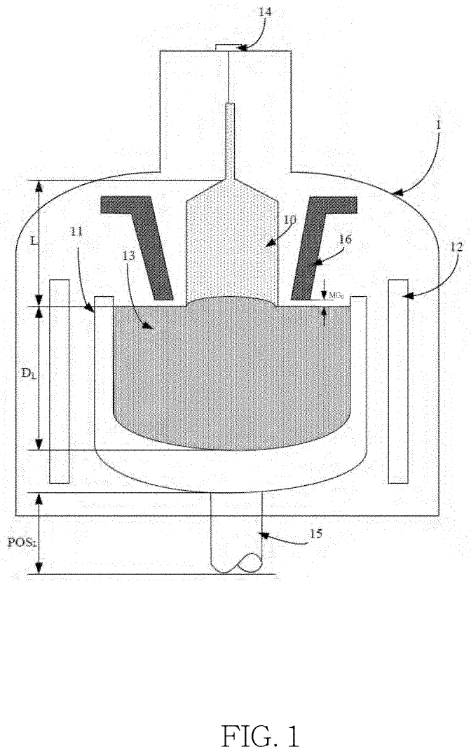

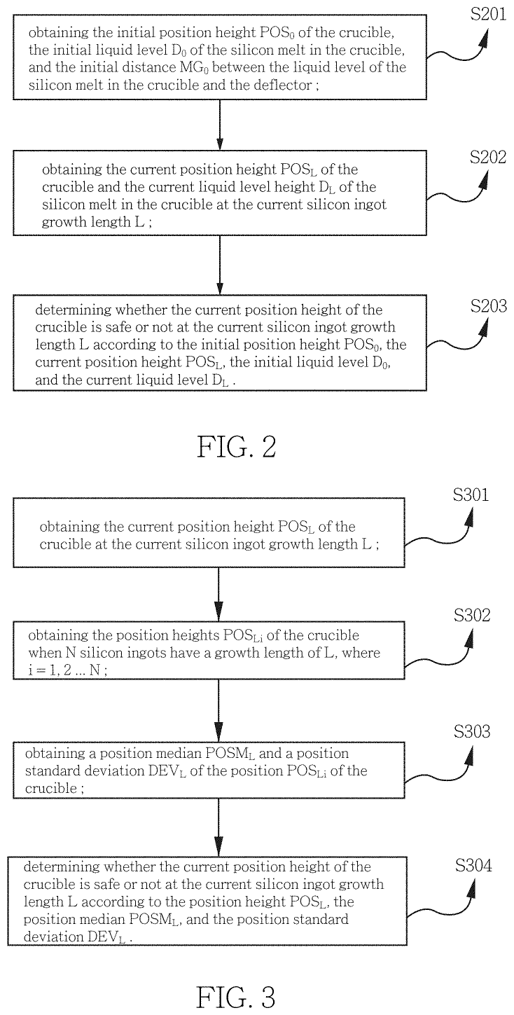

A method for controlling the safe lifting of a silicon melt crucible according to the present invention is exemplarily described with reference to FIG. 1 and FIG. 2. FIG. 1 is a schematic structural diagram of a semiconductor crystal growth device, while FIG. 2. is a flowchart of a method for controlling the safe lifting of a silicon melt crucible of an embodiment.

First, referring to FIG. 2, step S201 is performed: obtaining the initial position height POS₀ of the crucible, the initial liquid level D₀ of the silicon melt in the crucible, and the initial distance MG₀ between the liquid level of the silicon melt in the crucible and the deflector;

Before the semiconductor crystal growth device grows silicon ingots, the initial position height POS₀ of the crucible in the semiconductor crystal growth device, the initial liquid level D₀ of the silicon melt in the crucible, and the initial distance MG₀ between the silicon melt and the deflector, respectively are measured to obtain the respective initial values. This process can be obtained directly by a measurement device, such as an infrared distance meter.

With the growth of silicon rods in the semiconductor crystal growth device, the liquid level of silicon in the crucible gradually decreases, and the height of the liquid level of the silicon melt continuously decreases. In order to stabilize the growth of the silicon rods, the crucible needs to be moved upward to ensure that the crucible the stability of the silicon melt liquid level is to ensure that the distance between the silicon melt liquid level and the deflector in the crucible is stable within a certain range.

In order to control the position of the crucible up and down during the crystal pulling process to not exceed the safety setting range to ensure the stability of the silicon melt liquid level and the safety of the semiconductor growth device, the position of the crucible during the crystal pulling process is monitored.

With continued reference to FIG. 2, step S202 is executed: obtaining the current position height POS_{L} of the crucible and the current liquid level D_{L} of the silicon melt in the crucible at the current silicon ingot growth length L.

Referring to FIG. 1, during the crystal pulling process, when the length of the grown silicon ingot is L, the current position height POS_{L} of the crucible 11 and the current liquid level D_{L} of the silicon melt 13 in the crucible 11 are indicated in the illustration. Come out of the schematic. The distance between the liquid surface of the silicon melt 13 and the deflector 16 is not changed from the initial distance MG₀.

For example, the current position height POS_{L} of the crucible can be obtained by setting a measurement device (such as an infrared distance meter). For example, the current liquid level D_{L} of the silicon melt in the crucible can be obtained by setting a measurement device (such as an infrared distance meter) or by calculation.

Exemplarily, the step of obtaining the current level D_{L} of the liquid level of the silicon melt in the crucible by a calculation method includes: obtaining an initial mass G₀ of the silicon melt in the crucible and a current mass G_{L} at the currently generated silicon ingot length L; according to the initial mass G₀ of the silicon melt in the crucible and the current mass G_{L} of the currently generated silicon ingot, obtaining the volume Vᵣ of the current remaining silicon melt in the crucible; according to the volume Vᵣ of the body and the diameter of the crucible are calculated to obtain the current height D_{L} of the liquid level of the silicon melt in the crucible.

The process of obtaining the current height D_{L} of the silicon melt liquid level by a calculation method is described in further detail below:

First, the initial mass G₀ of the silicon melt in the crucible and the current mass G_{L} at the currently generated silicon ingot length L are obtained. The initial mass of the silicon melt in the crucible can be obtained from the setting in the semiconductor growth device before the silicon growth column is grown by the semiconductor growth device, which is obtained by direct measurement.

According to an embodiment of the present invention, the current mass G_{L} at the currently generated silicon ingot length L is obtained by direct measurement. Exemplarily, a weighing device such as a spring scale is provided on the crystal pulling device. During the crystal pulling process, as the silicon ingot grows, the current mass G_{L} of the grown silicon ingot at different lengths L is measured on the spring scale in real time.

According to another embodiment of the present invention, the obtaining the current mass G_{L} at the currently generated silicon ingot length L is obtained by a calculation method:

G_{L}=(∫ Area_{L} dL)*ρ_{Si}.

Among them, Area_{L} is the cross-sectional area of the silicon ingot, which can be obtained by setting the semiconductor growth device before crystal growth, and ρ_{Si} is the density of the silicon crystal.

Next, the volume V₀ of the silicon melt currently remaining in the crucible is obtained by the initial mass G₀ of the silicon melt in the crucible and the current mass G_{L} of the currently produced silicon ingot. The mass Gᵣ of the remaining silicon melt in the crucible is obtained from the initial mass G₀ of the silicon melt in the crucible and the current mass G_{L} of the currently produced silicon ingot. According to the mass volume formula:

V₀=G_{L}/ρ_{Si},

Among them, ρ_{Sil} is the density of liquid silicon.

Finally, the current height D_{L} of the liquid level of the silicon melt in the crucible is calculated according to the volume Vᵣ of the current remaining silicon melt of the crucible and the diameter d of the crucible.

Specifically, when the crucible is cylindrical, the following formula is used to calculate the formula.

D_{L}=Vᵣ/(π(d/2)²),

Alternatively, D_{L} can be calculated from a numerical solution that satisfies Vᵣ=∫₀^{D}^{_{L}}πr_{D}²*dD, where r_{D} is the radius of the crucible at the depth D.

At this point, obtaining of the values of the initial position height POS₀ of the crucible, the initial liquid level D₀ of the silicon melt in the crucible, the initial distance MG₀ between the liquid level of the silicon melt in the crucible and the deflector, the current position height POS_{L} of the crucible and the current liquid level height D_{L} of the silicon melt in the crucible at the currently generated silicon ingot length L are completed.

It should be understood that in this embodiment, L represents an uncertain value, and in this embodiment, it is indicated that the method of the present invention is highly safe for the current position of the crucible at any length of the silicon ingot and/or the silicon melt in the crucible the liquid level position is judged.

Next, referring to FIG. 2, step S203 is executed: determining whether the current position height of the crucible is safe or not at the current silicon ingot growth length L according to the initial position height POS₀, the current position height POS_{L}, the initial liquid level D₀, and the current liquid level D_{L}, where:
when α₀POS_{L}−α₁POS₀<β₀D₀−β₁D_{L}+β₂MG₀+L_{S}, the current position of the crucible is highly secure,
when α₀POS_{L}−α₁POS₀>β₀D₀−β₁D_{L}+β₂MG₀+L_{S}, the current position of the crucible is highly unsafe; wherein α₀, α₁, β₀, β₁, and β₂ are coefficient factors, and the L_{S} is a preset safety control height margin.

It should be understood that α₀, α₁, β₀, β₁, and β₂ can take any real value as the coefficient factors, which can be set by those skilled in the art according to the actual application situation. Ls is used to set the safety control height margin. It is also a value set by those skilled in the art according to the actual application. It is at least not lower than the position of the crucible at the beginning of the production of semiconductor crystals, and the maximum does not exceed the position height of the crucible when the semiconductor crystal is completed.

Exemplarily, in this embodiment, the values of α₀, α₁, β₀, β₁, and β₂ are 1. With this value, POS_{L}−POS₀ is a real-time measurement of the position height of the crucible during the growth of the silicon ingot. D₀−D_{L} is the calculated value of the crucible position change during the growth of the silicon ingot (also the change of the liquid level of the silicon melt in the crucible). During the stable pulling process, the real-time measurement value of the crucible position height change should be consistent with the crucible position change. The calculated values are not much different. To avoid the danger of the crucible rising too high and colliding with the deflector, set D₀−D_{L}+MG₀ as the maximum value of the actual measured value of the crucible position change. Because in the actual process, accurate calculation and measurement cannot be achieved, a safe control height margin L_{S} is set, and when POS_{L}−POS₀<D₀−D_{L}+MG₀+L_{S}, the position of the crucible is within the safe range to further Increase the reliability of safety judgment.

In one embodiment according to the present invention, the method for controlling the safe lifting of the silicon melt crucible further includes according to the initial position height POS₀, the current position height POS_{L}, the initial liquid level height D₀, and the current liquid level height D_{L} to determine whether the crucible is currently in a stable range. The crucible position that is too high or low will cause the liquid level position in the crucible to be too high or too low to cause instability, which will further damage the quality of the grown silicon ingot. For this reason, the judgment of the stability of the liquid surface position in the crucible is added.

Exemplarily, whether the position of the silicon melt liquid level in the crucible is stable at the currently generated silicon ingot length L is determined according to the following rules:
when α₀POS_{L}−α₁POS₀<β₀D₀−β₁D_{L}+β₂MG₀+L_{U} and α₀POS_{L}−α₁POS₀>β₀D₀−β₁D_{L}+β₂MG₀−L_{L}, the position of the liquid surface in the crucible is stable;
when α₀POS_{L}−α₁POS₀>β₀D₀−β₁D_{L}+β₂2MG₀+L_{U} or α₀POS_{L}−α₁POS₀<β₀D₀−β₁D_{L}+β₂MG₀−L_{L}, the position of the liquid surface in the crucible is unstable;

Among them, α₀, α₁, β₀, β₁, and β₂ are coefficient factors, and L_{U} and L_{L} are the set liquid level upper limit and the set liquid level lower limit control margin, respectively.

Similarly, α₀, α₁, β₀, β₁, and β₂ can take any real value as the coefficient factors, which can be set by those skilled in the art according to the actual application situation. L_{U} and L_{L} are used to set the upper limit of the liquid level and the control margin of the lower limit of the liquid level. These values are also set by those skilled in the art according to the actual application. In order to control the stable growth of the semiconductor crystal, the liquid level of the silicon melt can float between the upper and lower limits.

Exemplarily, in this embodiment, the values of α₀, α₁, β₀, β₁, and β₂ are 1. Under this value, the same as the safety judgment, the real-time measured value of the crucible position change POS_{L}−POS₀ and the change of the silicon melt liquid level in the crucible are controlled online D₀−D_{L}+MG₀+L_{U} and controlled offline D₀−D_{L}+MG₀−L_{L} is compared to judge the stability of the liquid surface position in the crucible. When the real-time measured value of the position change of the crucible POS_{L}−POS₀ is higher than the control on line D₀−D_{L}+MG₀+L_{U} or lower than the control off-line D₀−D_{L}+MG₀−L_{L} in the crucible, it is judged that the liquid level position is unstable.

In one example according to the present invention, when it is determined that the position of the crucible is outside the safe range, the crucible is locked at the current position without moving up and down. To avoid the crucible colliding with the deflector, so as to avoid a safety accident.

In one embodiment according to the present invention, when it is determined that the position of the liquid surface in the crucible is unstable, an alarm is issued. At this time, the process operator can adjust the semiconductor crystal growth device according to the alarm to avoid the growth of the damaged silicon crystal rod.

### Embodiment Two

In the first embodiment, a method for determining the crucible position safety and the stability of the silicon melt liquid level based on the measured and calculated crucible position and the position of the silicon melt liquid level in the crucible is described. In this embodiment, a statistical method will be provided to use the statistical data during the growth of silicon ingots under multiple tests with a safe crucible position and a stable silicon melt liquid level for the safety of subsequent silicon ingot growth processes.

Specifically, referring to FIG. 3, a method for controlling the safe lifting of a silicon melt crucible according to this embodiment is exemplarily described.

First, referring to FIG. 3, step S301 is performed: obtaining the current position height POS_{L} of the crucible at the current silicon ingot growth length L.

For example, the current position height POS_{L} of the crucible can be obtained by setting a measurement device (such as an infrared distance meter). During the growth of the semiconductor crystal, the position height of the crucible is measured in real time, so that the position of the crucible is monitored in real time, which effectively avoids the occurrence of a safety accident due to the crucible's collision with the deflector during the growth of the semiconductor crystal and the crucible The liquid level of the middle silicon melt is unstable and the growth defects of noise semiconductor crystals are defective.

Next, referring to FIG. 3, step S302 is performed: obtaining the position heights POS_{Li} of the crucible when N silicon ingots have a growth length of L, where i=1, 2 . . . N.

This step can be obtained by statistical methods. In the actual operation process, the process of growing the silicon ingot multiple times is monitored in real time, and the data of the crucible position heights during the stable growth of the silicon ingot are obtained. For example, the growth process of N silicon ingots is monitored. During the monitoring process, the crucible position heights are sequentially obtained every L length of each silicon ingot. Exemplarily, the growth process of 100 silicon ingots is monitored, wherein the length of each silicon ingot is 1000 mm. During the growth of each silicon ingot, the crucible position heights were obtained every 50 mm from the initial growth. Therefore, each silicon ingot will obtain the position of the silicon ingot 20 times. The setting of the crucible position height for every 50 mm growth of each silicon ingot is based on the diameter of the ingot, the diameter of the crucible, and the distance between the liquid surface and the deflector in actual use to ensure the crucible position obtained during the growth has sufficient density.

It should be understood that, in the foregoing embodiment, the number of silicon ingots is set to 100, and obtaining the crucible position height for each silicon ingot growth every 50 mm is merely exemplary. Any number of silicon ingots, as well as obtaining crucible positions for any number of lengths of growth, are applicable to the present invention.

After counting the positions of the crucibles at different growth lengths during the growth of the N silicon ingots described above, for the growth process of the silicon rods currently being processed, the positions of the N silicon rods when the growth length is L are obtained. The height of the crucible is POS_{Li}.

Next, referring to FIG. 3, step S303 is performed: obtaining the position median POSM_{L} and the position standard deviation DEV_{L} of the position POS_{Li} of the crucible.

The median position POSM_{L} of the position of the crucible POSM_{L} represents the median value of the position of the crucible when the length of the N ingots is L.

The position standard deviation of the position of the crucible POS_{Li}, DEV_{L} represents the degree of dispersion of the position of the crucible when the length of the N ingots is L. Using the median and standard deviation as the comparison standard, the difference between the current crucible position height POS_{L} and the crucible position POS_{Li} when the silicon rod grown in the current silicon rod growth process is L compared with the position standard deviation DEV_{L}, the crucible at the current position height is judged by judging the extent to which the current position height of the crucible POS_{L} deviates from the median position POSM_{L} when the growth length of the silicon ingot grown in the current silicon rod growth process is L. Whether it is within the safe range. The statistical method is used to determine whether the crucible at the current crucible position height is within a safe range, so that the comparison result takes into account the environmental factors and component factors in the actual process, and increases the accuracy of the judgment result.

The above-mentioned obtaining of the position of the crucible according to the position of the crucible POS_{Li}, the position median POSM_{L} and the position standard deviation DEV_{L} are performed using a formula for mathematically calculating the median and standard deviation, which is a technique well known to those skilled in the art. Therefore, the details will not be described for simplicity reason.

According to an embodiment of the present invention, a method for obtaining the position POSᵢ of the crucible when N silicon ingots have a growth length of L includes:
obtaining the position heights POS_{iM} of the crucible for each silicon crystal rod at each M length of growth;
obtaining the position POS_{Li} of the crucible at the growth length L for each silicon ingot from a plurality of the position heights POS_{iM} of each silicon ingot.

According to an embodiment of the present invention, the method for obtaining the position median POSM_{L} and the position standard deviation DEV_{L} of the position POSᵢ of the crucible includes:
obtaining the median position POSM_{M} and position standard deviation DEV_{M} of the crucible for each length of growth M according to the POS_{iM}, and draw them into a table or curve, respectively.

In the method for obtaining the position of the crucible when the growth length of the N silicon ingots is L and the method for obtaining the position median of the position of the crucible and the position median POSM_{L} and the position standard deviation DEV_{L}, Data set acquisition determines whether the current position height of the crucible when the growing length of the silicon ingot in the actual growth process is L is safe. This makes the method of obtaining data during the determination process simple and efficient.

Obtain from the table or curve the median position POSM_{L} and position standard deviation DEV_{L} of the crucible at the ingot growth length L. The data of the monitoring process of the previous N silicon ingots is collected to form a table or curve, which can be used at any time in the subsequent silicon ingot growth process, which simplifies the current position of the crucible at each growth length during the subsequent silicon ingot growth process. It is highly safe. Process of judging properties and stability of liquid level of silicon melt in crucible.

Next, referring to FIG. 3, step S304 is executed: determining whether the current position height of the crucible is safe or not at the current silicon ingot growth length L according to the position height POS_{L}, the position median POSM_{L}, and the position standard deviation DEV_{L}.

Exemplarily, whether the current height of the crucible is safe or not at the current silicon ingot growth length L is determined according to the following rules:
when γ₀POS_{L}−γ₁POSM_{L}<DEV_{L}×y_{S}, the position height of the crucible is within a safe range,
when γ₀POS_{L}−γ₁POSM_{L}>DEV_{L}×y_{S}, the position height of the crucible is outside the safe range, wherein γ₀ and γ₁ are coefficient factors, and γ_{S} is a set safety control factor.

Both γ₀ and γ₁ are arbitrary real numbers, and those skilled in the art can set them according to the actual application. y_{S} can be preset by the process operator according to the actual process environment and crystal growth setting conditions. Exemplarily, 0<y_{S}<10, γ₀ and γ₁ are both 1.

In an embodiment according to the present invention, the method for controlling the safe lifting of the silicon melt crucible further includes determining whether the liquid level of the silicon melt in the crucible is stable or not at the current silicon ingot growth length L based on the position height POS_{L}, the position median POSM_{L}, and the position standard deviation DEV_{L}.

Exemplarily, it is determined whether the position of the liquid level of the silicon melt in the crucible is stable at the current silicon ingot growth length L according to the following rules:

when γ₀POS_{L}−γ₁POSM_{L}<DEV_{L}×y_{U} and γ₀POS_{L}−γ₁POSM_{L}>DEV_{L}×y_{L}, the position of the liquid surface in the crucible is stable,
when γ₀POS_{L}−γ₁POSM_{L}>DEV_{L}×y_{U} or γ₀POS_{L}−γ₁POSM_{L}<DEV_{L}×y_{L}, the position of the liquid surface in the crucible is unstable.

wherein γ₀ and γ₁ are coefficient factors, and y_{U} and y_{L} are the highest factor and the lowest factor respectively.

Similarly, γ₀ and γ₁ are arbitrary real numbers, and those skilled in the art can set them according to actual applications. y_{U} and y_{L} can be set by the process operator according to the actual process environment and crystal growth setting conditions. Exemplarily, 0<y_{U}<10, 0<y_{L}<10, where y_{U} is less than y_{S}, and y₀ and y₁ are both 1.

Similarly, compare the difference between the current position height POS_{L} of the crucible and the position median POSM_{L} of the crucible position POS_{Li} at the current silicon ingot growth length L, and the position standard deviation DEV_{L}. Determining the extent to which the current position height of the crucible when the growth length of the silicon ingot grown in the current silicon ingot growth process is at a position POS_{L} deviates from the position median POSM_{L}, and whether the liquid level of the silicon melt in the crucible at the current position height stable. The statistical method is used to determine whether the position of the silicon melt liquid level in the crucible at the current crucible position height is stable, so that the comparison results take into account the environmental factors and component factors in the actual process, and increase the accuracy of the judgment results.

It should be understood that in this embodiment, L represents an uncertain value, and in this embodiment, it is indicated that the method of the present invention is highly safe for the current position of the crucible at any length of the silicon ingot and/or the silicon melt in the crucible the liquid level position is judged.

In one embodiment according to the present invention, when it is determined that the position of the crucible is outside the safe range, the crucible is locked at the current position without moving up and down. To avoid the crucible colliding with the deflector, so as to avoid a safety accident.

In one embodiment according to the present invention, when it is determined that the position of the liquid surface in the crucible is unstable, an alarm is issued. At this time, the process operator can adjust the semiconductor crystal growth device according to the alarm to avoid the growth of the damaged silicon crystal rod.

### Embodiment Three

The invention also provides a device for controlling the safe lifting of a silicon melt crucible, comprising:
a memory and a processor storing executable computer program instructions, and when the processor executes the executable computer program instructions, the processor executes the method according to the first embodiment or the second embodiment.

A device for controlling the safe lifting of the silicon melt crucible is set in the semiconductor crystal growth device. The crucible position and the liquid level position in the crucible are used to determine whether the current position of the crucible during the crystal pulling process is within a safe range. The crucible's up and down movement exceeds the limit and damage occurs. At the same time, the stability of the silicon melt liquid level in the crucible during its up and down movement further ensures the stable growth of the silicon ingot.

Exemplarily, the device for controlling the safe lifting of the silicon melt crucible further includes a locking device. When the processor determines that the position of the crucible is outside the safe range, the locking device locks the crucible at the current position without Move up and down.

Exemplarily, the device for controlling the safe lifting of the silicon melt crucible further includes an alarm device. When the processor determines that the position of the liquid surface in the crucible is unstable, the alarm device issues an alarm.

In summary, according to the method and device for controlling the safe lifting of a silicon melt crucible, according to the crucible position and the liquid level position in the crucible, it is judged whether the current position of the crucible during the crystal pulling process is within a safe range and avoids pulling. During the crystal process, the crucible is damaged due to the up and down movement of the crucible. At the same time, the stability of the silicon melt liquid level in the crucible during the up and down movement of the crucible is further guaranteed, and the stable growth of the silicon ingot is further ensured.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A method for controlling the safe lifting of a silicon melt crucible, comprising:
obtaining an initial position height POS₀ of the crucible, an initial liquid level D₀ of the silicon melt in the crucible, and an initial distance MG₀ between the liquid level of the silicon melt in the crucible and the deflector;
obtaining a current position height POS_{L} of the crucible and a current liquid level height D_{L} of the silicon melt in the crucible at a current silicon ingot growth length L;
determining whether the current position height of the crucible is safe or not at the current silicon ingot growth length L according to the initial position height PO₀, the current position height POS_{L}, the initial liquid level D₀, and the current liquid level height D_{L}.

2. The method according to claim 1, wherein whether the current position height of the crucible is safe or not at the current silicon ingot growth length L is determined according to the following rules:
When α₀POS_{L}−α₁POS₀<β₀D₀−β₁D_{L}+β₂MG₀+L_{S}, the current position height of the crucible is highly secure;
When α₀POS_{L}−α₁POS₀>β₀D₀−β₁D_{L}+β₂MG₀+L_{S}, the current position height of the crucible is highly unsafe;
wherein α₁, α₁, β₀, β₁, and β₂ are coefficient factors, and L_{S} is a preset safety control height margin.

3. The method according to claim 1, further comprising judging whether the position of the liquid surface of the silicon melt in the crucible is stable or not at the current silicon ingot growth length L according to the initial position height POS₀, the current position height POS_{L}, the initial liquid level height D₀, and the current liquid level height D_{L}.

4. The method according to claim 3, wherein whether the position of the liquid surface of the silicon melt in the crucible is stable or not is judged according to the following rules:
when α₀POS_{L}−α₁POS₀<β₀D₀−β₁D_{L}+β₂MG₀+L_{U} and α₀POS_{L}−α₁POS₀>β₀D₀−β₁D_{L}+β₂MG₀−L_{L}, the position of the silicon melt liquid level in the crucible is stable;
when α₀POS_{L}−α₁POS₀>β₀D₀−β₁D_{L}+β₂MG₀+L_{U} or α₀POS_{L}−α₁POS₀<β₀D₀−β₁D_{L}+β₂MG₀−L_{L}, the position of the liquid level of the silicon melt in the crucible is unstable;
wherein α₀, α₁, β₀, β₁, and β₂ are coefficient factors, and L_{U} and L_{L} are the control margins for setting the upper and lower limits of the liquid level, respectively.

5. The method according to claim 4, wherein the step of obtaining the current liquid level D_{L} of the liquid level of the silicon melt in the crucible comprises:
obtaining an initial mass G₀ of the silicon melt in the crucible and a current mass G_{L} of the silicon ingot at the current silicon ingot growth length L;
obtaining a volume Vᵣ of the silicon melt currently remaining in the crucible according to the initial mass G₀ of the silicon melt in the crucible and the current mass G_{L};
calculating the current liquid level height D_{L} of the silicon melt in the crucible according to the volume Vᵣ of the current remaining silicon melt of the crucible and the diameter of the crucible.

6. The method according to claim 5, wherein the obtaining the current mass G_{L} of the silicon ingot at the current silicon ingot growth length L is obtained by a formula:
G_{L}=(∫ Area_{L} dL)*ρ_{Si}
wherein Area_{L} is the cross-sectional area of the silicon ingot, and ρ_{Si} is the density of the silicon crystal.

7. The method according to claim 5, wherein the acquiring the quality G_{L} of the currently generated silicon ingot is obtained by directly measuring the mass of the currently generated silicon ingot.

8. The method according to claim 2, wherein when it is judged that the position of the crucible is outside the safe range, the crucible is locked at the current position without moving up and down.

9. The method according to claim 4, wherein when the position of the liquid surface in the crucible is judged to be unstable, an alarm is issued.

10. A method for controlling the safe lifting of a silicon melt crucible, comprising:
obtaining a current position height POS_{L} of the crucible at a current silicon ingot growth length L;
obtaining position heights POS_{Li} of the crucible when N silicon ingots have a growth length of L, where i=1, 2 . . . N;
obtaining a position median POSM_{L} and a position standard deviation DEV_{L} of the position POS_{Li} of the crucible;
determining whether the current position height of the crucible is safe or not at the current silicon ingot growth length L according to the position height POS_{L}, the position median POSM_{L}, and the position standard deviation DEV_{L}.

11. The method according to claim 10, wherein whether the current position height of the crucible is safe or not at the current silicon ingot growth length L is judged according to the following rules:
when γ₀POS_{L}−γ₁POSM_{L}<DEV_{L}×y_{S}, the current position height of the crucible is highly safe;
when γ₀POS_{L}−γ₁POSM_{L}>DEV_{L}×y_{S}, the current position height of the crucible is highly unsafe;
wherein γ₀ and γ₁ are coefficient factors, and y_{S} is a preset safety control factor.

12. The method according to claim 10, further comprising judging whether the position of the liquid surface of the silicon melt in the crucible is stable or not at the current silicon ingot growth length L according to the position height POS_{L}, the position median POSM_{L}, and the position standard deviation DEV_{L}.

13. The method according to claim 12, wherein whether the position of the liquid surface of the silicon melt in the crucible is stable or not at the current silicon ingot growth length L is determined according to the following rules:
when γ₀POS_{L}−γ₁POSM_{L}<DEV_{L}×y_{U} and γ₀POS_{L}−γ₁POSM_{L}>DEV_{L}×y_{L}, the position of the liquid level of the silicon melt in the crucible is stable;
when γ₀POS_{L}−γ₁POSM_{L}>DEV_{L}×y_{U} or γ₀POS_{L}−γ₁POSM_{L}<DEV_{L}×y_{L}, the position of the liquid level of the silicon melt in the crucible is unstable;
wherein γ₀ and γ₁ are coefficient factors, and y_{U} and y_{L} are the highest factor and the lowest factor respectively.

14. The method according to claim 10, wherein the step of obtaining the position POS_{Li} of the crucible when N silicon ingots have a growth length of L comprises:
obtaining position heights POS_{iM} of the crucible for each silicon crystal rod at each M length of growth;
obtaining each position POS_{Li} for each silicon ingot of the crucible at the current silicon ingot growth length L from a plurality of the position heights POS_{iM} of each silicon ingot.

15. The method according to claim 14, wherein the step of obtaining the position median POSM_{L} and the position standard deviation DEV_{L} of the position POSᵢ of the crucible comprises:
obtaining the median position POSM_{M} and position standard deviation DEV_{L} of the crucible for each length of growth M according to the POS_{iM}, and plotting them into a table or curve, respectively;
obtaining the median position POSM_{L} and position standard deviation DEV_{L} of the crucible at the current silicon ingot growth length L from the table or curve.

16. The method according to claim 11, wherein when it is judged that the position of the crucible is outside the safe range, the crucible is locked at the current position without moving up and down.

17. The method according to claim 13, wherein when the position of the liquid surface in the crucible is judged to be unstable, an alarm is issued.

18. A device for controlling the safe lifting of a silicon melt crucible, comprising:
a memory and a processor storing executable computer program instructions, and when the processor executes the executable computer program instructions, the processor executes the method as claimed in claim 1.

19. The device according to claim 18, further comprising a locking device, when the processor determines that the position of the crucible is outside the safe range, the locking device locks the crucible at the current position without moving up and down.

20. The device according to claim 18, further comprising an alarm device, wherein when the processor determines that the position of the liquid surface in the crucible is unstable, the alarm device issues an alarm.
